(19) United States
(12) Patent Application Publication
(10) Pub. No.: US 2013/0221422 A1
(43) Pub. Date: Aug. 29, 2013

(54) MEMORY DEVICE AND METHOD OF MANUFACTURE THEREOF

(71) Applicant: Kabushiki Kaisha Toshiba, (US)

(72) Inventors: Mitsuhiko NODA, Mie (JP); Hiroyuki Kutsukake, Kanagawa (JP); Kazuya Ohuchi, Kanagawa (JP); Mitsuhiro Noguchi, Kanagawa (JP)

(73) Assignee: Kabushiki Kaisha Toshiba, Tokyo (JP)

(21) Appl. No.: 13/746,097

(22) Filed: Jan. 21, 2013

(30) Foreign Application Priority Data
Feb. 28, 2012 (JP) 2012-042445

(51) Int. Cl. H01L 29/66; H01L 29/40; H01L 29/788

(52) U.S. Cl. CPC H01L 29/66825; H01L 29/788; H01L 29/401
USPC 257/316; 438/266; 438/586

(57) ABSTRACT

A memory device is provided with a floating gate electrode film formed in a memory cell region, a first inter-electrode insulating film formed on the floating gate electrode film, a control gate electrode film formed on the first inter-electrode insulating film, a lower conductive film formed in a peripheral circuit region, a second inter-electrode insulating film formed on the lower conductive film, an upper conductive film formed on the second inter-electrode insulating film, and a pair of contacts that is separated from each other, is connected to the lower conductive film from the upper side, and is not connected to the upper conductive film. Materials of the lower conductive film and the floating gate electrode film are the same. Materials of the second inter-electrode insulating film and the first inter-electrode insulating film are the same. Materials of the upper conductive film and the control gate electrode film are the same.

### CROSS-REFERENCE TO RELATED APPLICATION

This application is based upon and claims the benefit of priority from Japanese Patent Application No. 2012-042445, filed Feb. 28, 2012; the entire contents of which are incorporated herein by reference.

### FIELD Embodiments described herein relates generally to a memory device and its manufacturing method.

### BACKGROUND

The capacitance of memory devices such as NAND-type flash memory can be increased by miniaturizing memory cells, which would also significantly reduce the cost per bit of memory. However, further cost reductions will be needed in the future.

### DESCRIPTION OF THE DRAWINGS

FIG. 1A to FIG. 1D are plan views illustrating a memory device according to a first embodiment.

FIG. 2A to FIG. 2D are cross sections illustrating the memory device according to the first embodiment.

FIG. 3A to FIG. 3D are plan views illustrating a method for manufacturing the memory device according to the first embodiment.

FIG. 4A to FIG. 4D are cross sections illustrating the method for manufacturing the memory device according to the first embodiment.

FIG. 5A to FIG. 5D are plan views illustrating the method for manufacturing the memory device according to the first embodiment.

FIG. 6A to FIG. 6D are cross sections illustrating the method for manufacturing the memory device according to the first embodiment.

FIG. 7A to FIG. 7D are plan views illustrating a memory device of a comparative example.

FIG. 8A to FIG. 8D are cross sections illustrating the memory device of the comparative example.

FIG. 9A is a plan view illustrating a resistance element of a memory device according to a second embodiment, and FIG. 9B is a cross section taken along B-B′ line in FIG. 9A.

### DETAILED DESCRIPTION

Embodiments provide a low cost memory device and its manufacturing method.

In general, example embodiments will be explained with reference to the drawings.

According to an embodiment of the present disclosure, a memory device has a memory cell region and a peripheral cell region. The memory device is provided on a semiconductor substrate. The memory device includes a lower layer insulating film (first insulating film) formed on the semiconductor substrate, a floating gate electrode film (first conductive film) formed on the lower layer insulating film in a memory cell region, a first inter-electrode insulating film (second insulating film) formed on the floating gate electrode film, a control gate electrode film (second conductive film) formed on the first inter-electrode insulating film, a lower conductive film (first conductive film) formed on the lower layer insulating film in a peripheral circuit region, a second inter-electrode insulating film (second insulating film) formed on the lower conductive film, an upper conductive film (second conductive film) formed on the second inter-electrode insulating film, and at least one contact (first contact)connected to the lower conductive film, but not connected to the upper conductive film.

The lower conductive film is the same material type as the floating gate electrode film. The second inter-electrode insulating film is the same material type as the first inter-electrode insulating film. The upper conductive film is the same material type as the control gate electrode film. The layers may have different names depending on the region of the device being discussed, such as the floating gate electrode film in the memory region is otherwise the same as the lower conductive film in the peripheral circuit region.

A method for manufacturing a memory device according to the present disclosure includes a process that forms a lower layer insulating film on a semiconductor substrate; a process that forms a lower conductive film on the lower layer insulating film; a process that forms the lower conductive film into a wiring shape extending in a first direction by selectively removing the lower conductive film; a process that forms an inter-electrode insulating film on the lower conductive film; a process that forms an upper conductive film on the inter-electrode insulating film; a process that forms the upper conductive film into a wiring shape extending in a second direction intersecting with the first direction in the memory cell region by selectively removing the upper conductive film, the inter-electrode insulating film, and the lower conductive film to form several control gate electrode films, a floating gate electrode film by dividing the lower conductive film along both the first direction and the second direction, and a resistance laminate in which the lower layer insulating film, the lower conductive film, the inter-electrode insulating film, and the upper conductive film are sequentially laminated; a mask film formation process that covers the floating gate electrode film, the control gate electrode film, and the resistance laminate and forms a mask film in which a mask opening part is formed in part of an area on the resistance laminate; an etching process that forms an opening part in the upper conductive film, which is included in the resistance laminate, by applying etching using the mask film as a mask; a process that forms an interlayer dielectric that covers the floating gate electrode film, the control gate electrode film, and the resistance laminate; and a contact formation process that forms a pair of contacts penetrating through the interlayer dielectric, passes through the opening part, and arrives at the lower conductive film that is included in the resistance laminate, but is not connected to the upper conductive film.

First, the first embodiment will be explained.

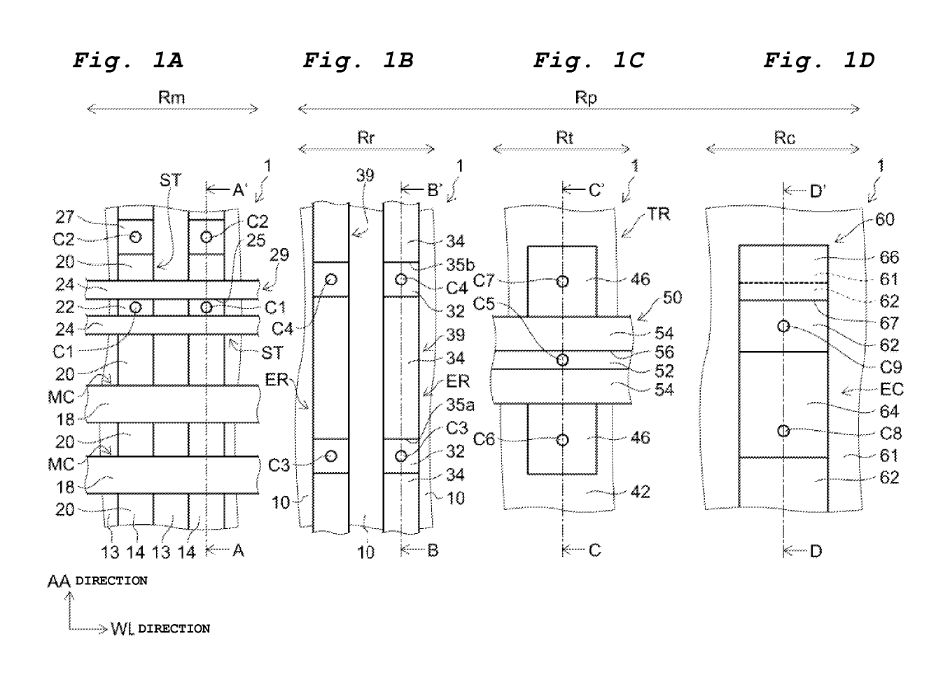

FIG. 1A to FIG. 1D show plan views illustrating a memory device according to this embodiment. FIG. 1A shows memory cells and selective gate transistors, FIG. 1B show resistance elements, FIG. 1C shows transistors, and FIG. 1D shows capacitive elements.

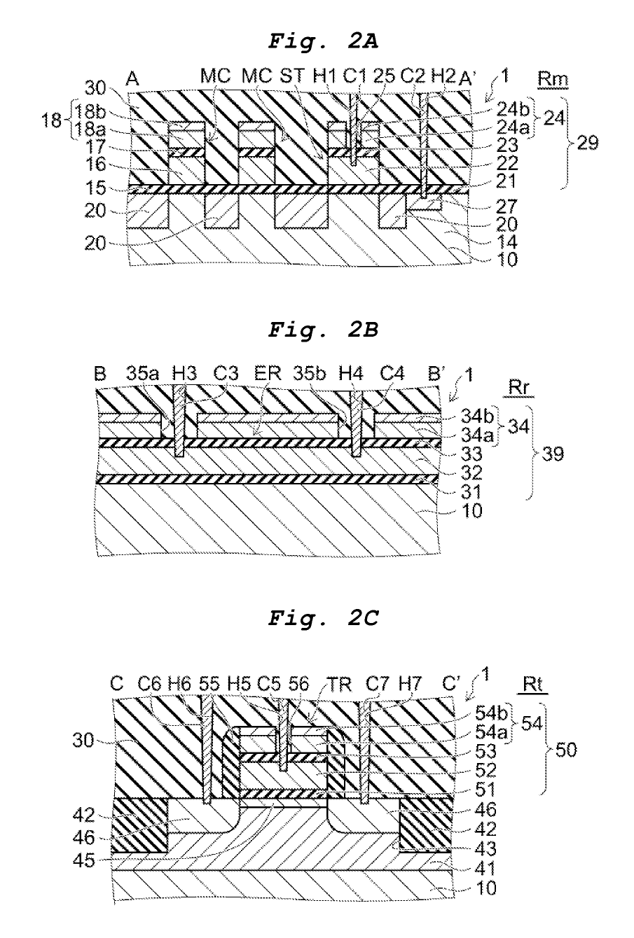

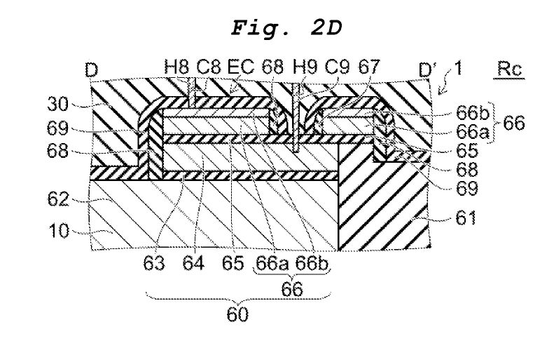

FIG. 2A to FIG. 2D show cross sections illustrating the memory device according to the first embodiment. FIG. 2A is a cross section along A-A′ line of FIG. 1A, FIG. 2B is a cross section along B-B′ line of FIG. 1B, FIG. 2C is a cross section along C-C′ line of FIG. 1C, and FIG. 2D is a cross section of D-D′ line of FIG. 1D.

Here, for the sake of easy viewing of the drawing, only conductive parts are shown in the plan views of FIG. 1A to FIG. 1D, and the insulating parts are not shown. However, element isolation insulators (STI) are shown in the drawings. This also applies to the other plan views, which will be mentioned later.

The memory device according to this embodiment is, for example, an NAND-type flash memory.

As shown in FIG. 1A to FIG. 1D and FIG. 2A to FIG. 2D, a silicon substrate 10 is installed in a memory device 1 of this embodiment.

In addition, in the memory device 1, a memory cell region Rm and a peripheral circuit region Rp are set. In the memory cell region Rm, several memory cells MC are formed in a matrix form, and each memory cell MC respectively stores information of 1 bit, for instance. In the peripheral circuit region Rp, peripheral circuits for driving the memory cells are formed. As will be mentioned later, resistance elements, transistors, and capacitive elements are installed in the peripheral circuits.

Next, as will be explained in detail, in the memory device 1, lower conductive films, insulating films, and upper conductive films are sequentially laminated, and this laminate is patterned to form various kinds of elements in each region. In addition, an opening part is formed in the upper conductive film to directly connect a partial contact to the lower conductive film.

First, the memory cell region Rm will be explained. As shown in FIG. 1A and FIG. 2A, in the memory cell region Rm, several pieces of element isolation insulators (Shallow Trench Isolation: STI) 13 extending in one direction (hereinafter, referred to “AA direction”) are periodically formed in an upper layer part of the silicon substrate 10. The upper layer portion of the silicon substrate 10 is divided into several pieces of active areas 14 extending in the AA direction by the STI 13. On the upper surface of the active areas 14, for example, a tunnel insulating film 15 composed of a silicon oxide is formed. On the tunnel insulating film 15, several floating gate electrode films 16 are installed. The floating gate electrode films 16 are intermittently and periodically arranged along the AA direction and the direction (hereinafter, referred to “WL direction”) generally orthogonal to the AA direction in a plane generally parallel to the substrate. The floating gate electrode films 16, for example, are formed of polysilicon into which impurities (dopants) have been introduced (doped), and the shape of each floating gate electrode film 16 is an island shape.

On the floating gate electrode films 16, inter-electrode insulating films (Inter Poly Dielectric: IPD film) 17 are formed. The IPD films 17, for example, are laminated insulating films in which a silicon oxide film and a silicon nitride film are laminated. On the IPD films 17, several pieces of control gate electrode films 18 are formed. The shape of each floating gate electrode film 16 is a rectangular shape extending in the WL direction, and the control gate electrode films pass above several floating gate electrode films 16 arranged in a column along the WL direction.

In the control gate electrode film 18, a polysilicon layer 18a composed of polysilicon in which impurities have been introduced, and a metal layer 18b composed of a metal such as tungsten or nickel is formed on the polysilicon layer 18a. The metal layer 18b may also be a silicide layer.

In this manner, a layer of memory cells MC are formed above the active areas 14 that extend in the AA direction and are periodically arranged. The control gate electrode film pieces are arrayed periodically in the AA direction and extend in the WL direction. In this case, the control gate electrode films 18 operate as word lines. Therefore, in the memory region Rm, several memory cells MC are formed and arranged in a matrix form.

In addition, at both sides of a memory cell set including several pieces of control gate electrode films 18 on the upper surface of each active area 14, for example, gate insulating films 21 composed of a silicon oxide are formed. For example, lower conductive films 22 composed of polysilicon into which impurities have been introduced are formed on the gate insulating films 21. The lower conductive films 22 are arranged only in an area above the active areas 14, and their shape is an island shape.

On the lower conductive films 22, IPD films 23 are formed, and upper conductive films 24 are formed thereon. The IPD film 23, for example, is a laminated insulating film in which a silicon oxide film and a silicon nitride film are laminated. The gate insulating films 21, lower conductive films 22, IPD films 23, and upper conductive films 24 form a selective gate laminate 29. The shape of the selective gate laminate 29 is a wiring shape that extends in the WL direction and passes above the lower conductive films 22. In the upper conductive film 24, polysilicon layer 24a and a metal layer 24b are sequentially laminated from the lower layer side. In addition, groove-shaped opening parts 25 extending in the WL direction are formed in the IPD films 23 and the upper conductive films 24. The lower conductive films 22 are exposed to the bottom faces of the opening parts 25, which may extend partially into the lower conductive films 22.

Moreover, contact layers 27 are formed in an area opposite to the control gate electrode films 18 from the upper conductive films 24 in the upper layer portion of the active areas 14. Furthermore, source-drain regions 20 containing impurities are formed between a portion corresponding to the area right under the control gate electrode films 18 in the upper layer portion of the active area 14, a portion corresponding to the area right under the upper conductive films 24, and the contact layers 27. The active areas 14, a pair of source-drain regions 20, which sandwiches a portion corresponding to the area below the lower conductive films 22 in the active areas 14, gate insulating films 21, and lower conductive film 22 form a selective gate transistor ST.

On the silicon substrate 10, for example, an interlayer dielectric 30 composed of a silicon oxide is formed so that it covers the respective device elements. The interlayer dielectric 30 is arranged at both the memory cell region Rm and the peripheral circuit region Rp and is also embedded into the opening parts 25. On the interlayer dielectric 30, a source line (not shown in the drawing) extending in the WL direction is formed, and bit lines (not shown in the drawing) extending in the AA direction are formed thereon. The bit lines are arranged in the area directly above the active areas 14.

In addition, in the memory cell region Rm, contacts C1 and C2 are formed in the interlayer dielectric 30. The contact C1 extends in the vertical direction in the interlayer dielectric 30, passes through the opening part 25, and arrives at the upper surface of the lower conductive film 22. Therefore, the contact C1 is connected to the lower conductive film 22 from the upper side. The contact C1 is not connected to the upper conductive film 24. The contact C2 extends in the vertical direction in the interlayer dielectric 30, and its lower end is connected to the contact layer 27. The upper end of the contact C2 is connected to the source line, and the shape of the contacts C1 and C2 may be, for example, a circular shape from a top view. Contacts C3-C9, which will be mentioned later, are also similar.

Next, the peripheral circuit region Rp will be explained. In the peripheral circuit region Rp, a resistance element region Rr, transistor region Rt, and capacitive element region Rc are set.

First, the resistance element region Rr will be explained.

As shown in FIG. 1B and FIG. 2B, several pieces of wiring-shaped resistance laminates 39 extending in one direction are formed on the silicon substrate 10 in the resistance element region Rr of the peripheral circuit region Rp. In each resistance laminate 39, an insulating film 31, lower conductive film 32, IPD film 33, and upper conductive film 34 are sequentially laminated from the lower layer side.

The insulating film 31, for example, is composed of a silicon oxide, the lower conductive film 32, for example, is formed of polysilicon into which impurities have been introduced, and the IPD film 33, for example, is a laminated insulating film in which a silicon oxide film and a silicon nitride film are laminated. In addition, in the upper conductive film 34, a polysilicon layer 34a and a metal layer 34b are sequentially laminated from the lower layer side. In addition, in each resistance laminate 39, two opening parts 35a and 35b are formed in the IPD film 33 and the upper conductive film 34. The opening parts 35a and 35b are arranged at positions separated from each other in the extending direction of the resistance laminate 39.

Here, the shape of the resistance laminate 39 is not limited to a wiring shape but may be any shape that can obtain a desired resistance value. However, to prevent the inflow and outflow of noise, the resistance laminate 39 is preferably separated from the periphery. In addition, the insulating films 31 may be continuously formed among several pieces of resistance laminates 39.

The resistance laminate 39 is covered with the interlayer dielectric 30. The interlayer dielectric 30 is also embedded into the opening parts 35a and 35b. In the interlayer dielectric 30, contacts C3 and C4 extending in the vertical direction are formed. The contact C3 passes through the opening part 35a and arrives at the lower conductive film 32. In addition, the contact C4 passes through the opening part 35b and arrives at the lower conductive film 32. For this reason, at mutually separated positions in the same lower conductive film 32, the contacts C3 and C4 are connected to the lower conductive film 32 from the upper side. On the other hand, the contacts C3 and C4 are not connected to the upper conductive film 34. Therefore, the lower conductive film 32 composed of polysilicon is connected between the contacts C3 and C4, rendering a prescribed resistance value. In this manner, in the resistance element region Rr, a resistance element ER in which the lower conductive film 32 is a resistor is formed on the silicon substrate 10.

Next, the transistor region Rt will be explained.

As shown in FIG. 1C and FIG. 2C, in the transistor region Rt of the peripheral circuit region Rp, for example, a p-type well 41 is formed in the upper layer portion of the silicon substrate 10. In addition, element isolation insulators (STI) 42 are formed in the upper layer portion of the well 41, and part of the upper layer portion of the well 41 is divided from the other parts. Next, the area divided by the STI 42 in the well 41 is referred to an element area 43.

In an area above the central part in the width direction of the element area 43, a gate laminate 50 is formed. The shape of the gate laminate 50 has a wiring shape extended in one direction so that it passes through the area above the central area in the width direction of the element area 43. In the gate laminate 50, a gate insulating film 51, lower conductive film 52, IPD film 53, and upper conductive film 54 are sequentially laminated from the lower layer side. The gate insulating film 51, for example, is formed of a silicon oxide. The lower conductive film 52, for example, is formed of polysilicon into which impurities have been introduced. The IPD film 53, for example, is a laminated insulating film in which a silicon oxide film and a silicon oxide film are laminated. In the upper conductive film 54, a polysilicon layer 54a and a metal layer 54b are sequentially laminated from the lower layer side. In addition, for example, side walls 55 composed of a silicon nitride are formed on the side surfaces of the gate laminate 50. Moreover, in the gate laminate 50, an opening part 56 is formed in the IPD film 53 and the upper conductive film 54.

On the other hand, for example, a p-type channel region 45 is formed in a portion corresponding to the area below the gate laminate 50 in the element area 43, and for example, n-type source drain regions 46 are formed in two areas that sandwich the channel region 45 in the element area 43.

The gate laminate 50 and the side walls 55 formed on its side surfaces are covered with the interlayer insulating film 30. The interlayer insulating film 30 is also embedded inside the opening part 56. In the interlayer insulating film 30, contacts C5-C7 extending in the vertical direction are formed. The contact C5 passes through the opening part 56 and arrives at the lower conductive film 52. Therefore, the contact C5 is connected to the lower conductive film 52 from the upper side. The contact C5 is not connected to the upper conductive film 54. On the other hand, contacts C6 and C7 are connected to the source-drain regions 46 different from each other.

Therefore, a field-effect transistor TR in which the lower conductive film 52 is a gate electrode is formed in the transistor region Rt. The transistor TR, for example, may be a transistor constituting a logic circuit or may also be a transfer transistor for supplying a control potential to the control gate electrode film 18 of the memory cell region Rm.

Next, the capacitive element region Rc will be explained.

As shown in FIG. 1D and FIG. 2D, in the capacitive element region Rc of the peripheral circuit region Rp, an element isolation insulator (STI) 61 is formed in the upper layer portion of the silicon substrate 10. The upper layer portion of the silicon substrate 10 is divided into active areas 62 by the STI 61. The upper part of the STI 61 protrudes from the upper surface of the silicon substrate 10.

On the active area 62, a capacitive laminate 60 is formed. In the capacitive laminate 60, an insulating film 63, lower conductive film 64, IPD film 65, and upper conductive film 66 are sequentially laminated from the lower layer side. The insulating film 63, for example, is formed of a silicon oxide. The lower conductive film 64, for example, is formed of polysilicon into which impurities have been introduced. The end surface of the lower conductive film 64 contacts with the side surface of the upper part of the STI 61. In addition, the upper surface of the lower conductive film 64 has about the same height as that of the upper surface of the STI 61. The IPD film 65, for example, is a laminated insulating film in which a silicon oxide film and a silicon nitride film are laminated. In the upper conductive film 66, a polysilicon layer 66a and a metal layer 66b are sequentially laminated from the lower layer side. Part of the IDP film 65 and part of the upper conductive film 66 climb over the STI 61. Here, the shape of the capacitive laminate 60 is not particularly limited; however, the area of the lower conductive film 64 and the upper conductive film 66 is set to an area where the capacitance with a desired size can be realized.

In the capacitive laminate 60, an opening part 67 is formed in the area right on the lower conductive film 64 in the IPD film 65 and the upper conductive film 66. In addition, side wall insulating films 68 are formed on the side surfaces of the capacitive laminate 60. The side wall insulating film 68 is also formed on the inner surface of the opening part 67. In addition, for example, liner films 69 composed of a silicon nitride are formed so that they cover the capacitive laminate 60 and the side wall insulating films 68.

The capacitive laminate 60, side wall insulating film 68, and liner films 69 are covered with the interlayer dielectric 30. The interlayer dielectric 30 is also embedded into the opening part 67. In the interlayer dielectric 30, contacts C8 and C9 extending in the vertical direction are formed. The contact C8 penetrates through the liner film 69 and arrives at a metal layer 66b of the upper conductive film 66. Therefore, the contact C8 is connected to the upper conductive film 66 from the upper side. Here, the contact C8 is not connected to the lower conductive film 64. On the other hand, the contact C9 passes through the opening part 67 and arrives at the lower conductive film 64. Therefore, the contact C9 is connected to the lower conductive film 64 from the upper side. Here, the contact C9 is not connected to the upper conductive film 66.

Therefore, if the same potential (for example, potential Vss) as that of the active area 62 is applied to the contact C8 and a potential (for example, potential Vdd) different from that of the contact C8 is applied to the contact C9, a capacitance is generated between the lower conductive film 64 and the upper conductive film 66 through the IPD film 65 as a capacitive insulating film, and a capacitance is generated between the lower conductive film 64 and the active area 62 through the insulating film 63 as a capacitive insulating film. Therefore, in the capacitive element region Rc, a capacitive element EC in which the active area 62, lower conductive film 64, and upper conductive film 66 are capacitive electrodes and the insulating film 63 and the IPD film 65 are capacitive insulating films is formed.

Next, characteristics common to the respective elements will be explained.

As will be mentioned later, the floating gate electrode film 16 of the memory cell MC, lower conductive film 22 as a gate electrode of the selective gate transistor ST, lower conductive film 32 as a resistor of the resistance element ER, lower conductive film 52 as the gate electrode of the transistor TR, and lower conductive film 64 as a capacitive electrode of the capacitive element EC are formed by patterning of the same polysilicon film. Therefore, the materials of the floating gate electrode film 16, lower conductive film 22, lower conductive film 32, lower conductive film 52, and lower conductive film 64 are mutually the same. Here, in this specification, “the material is the same” means that the matrix is common. In other words, the floating gate electrode film 16, lower conductive film 22, lower conductive film 32, lower conductive film 52, and lower conductive film 64 include polysilicon as a common matrix. In addition, for example, the same impurities are introduced into these films, and their concentration is substantially the same, though it can be altered in accordance with the locations. In other words, the compositions of these films are approximately equal to each other, neglecting normal variations in processing results across substrate locations. Moreover, the thickness of these films is also approximately equal to each other, though it can be altered in accordance with the location during the film formation process or subsequent processing steps.

Furthermore, the IPD film 17 of the memory cell MC, IPD film 23 formed in the selective gate transistor ST, IPD film 33 formed in the resistance element region Rr, IPD film 53 formed in the transistor region Rt, and IPD film 65 as a capacitive insulating film of the capacitive element EC are formed by patterning of the same laminated film. Therefore, the materials of the IPD film 17, IPD film 23, IPD film 33, IPD film 53, and IPD film 65 are mutually the same. For example, the film structure, composition, and thickness of these IPD films are respectively, approximately equal to each other, neglecting normal variations in processing results across substrate locations. Here, in case the IPD films are laminated films, for example, the composition and the film thickness of each layer are approximately equal to each other between the IPD films, so that the average composition and the entire film thickness of the IPD films are approximately equal to each other. Other films are also similar.

In addition, the control gate electrode film 18 of the memory cell MC, upper conductive film 24 formed in the selective gate transistor ST, upper conductive film 34 formed in the resistance element region Rr, upper conductive film 54 formed in the transistor region Rt, and upper conductive film 66 as a capacitive insulating film of the capacitive element EC are formed by patterning of the same double layer film. Therefore, the materials of the control gate electrode film 18, upper conductive film 24, upper conductive film 34, upper conductive film 54, and upper conductive film 66 are mutually the same. For example, the structure, composition, and thickness of these films are respectively, approximately equal to each other, neglecting normal variations in processing results across substrate locations. For example, the composition and the film thickness of the polysilicon layers of each upper conductive film are approximately equal to each other, and the composition and the thickness of the metal layers of each upper conductive film are approximately equal to each other.

On the other hand, the tunnel insulating film 15 of the memory cell MC, gate insulating film 21 of the selective gate transistor ST, insulating film 31 formed in the resistance element region Rr, gate insulating film 51 of the transistor TR, and insulating film 63 as a capacitive insulating film of the capacitive element EC are part of the lower layer insulating films formed on the upper surface of the silicon substrate 10; however, these insulating films are not necessarily films formed in the same process. Therefore, the film thickness and the composition of the lower layer insulating films are not necessarily uniform but are sometimes different in accordance with the formation positions.

Next, the method for manufacturing the memory device of this embodiment will be explained.

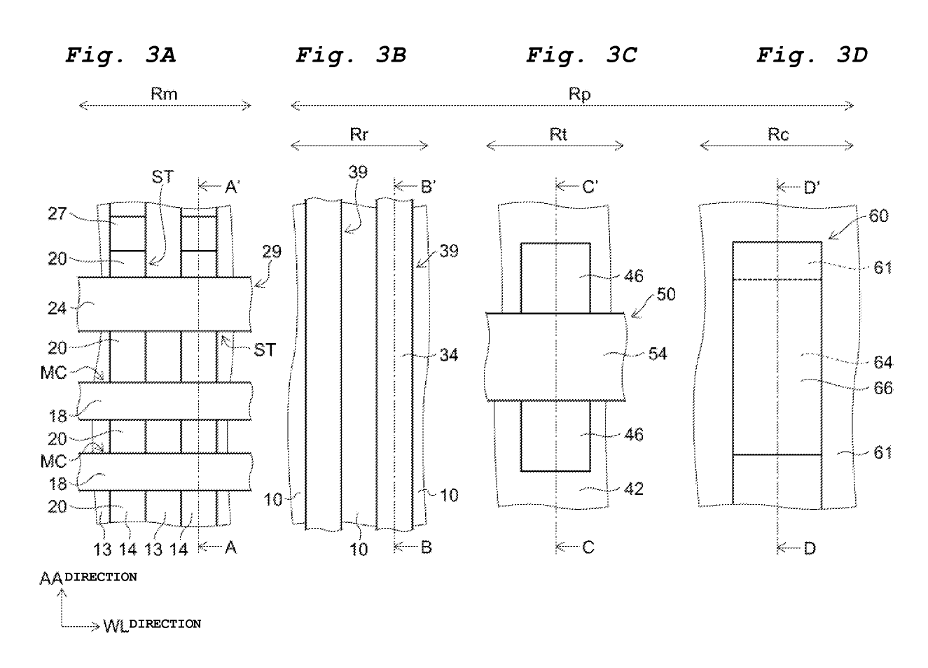

FIG. 3A to FIG. 3D are process plan views illustrating a method for manufacturing a memory device according to an embodiment of the present disclosure.

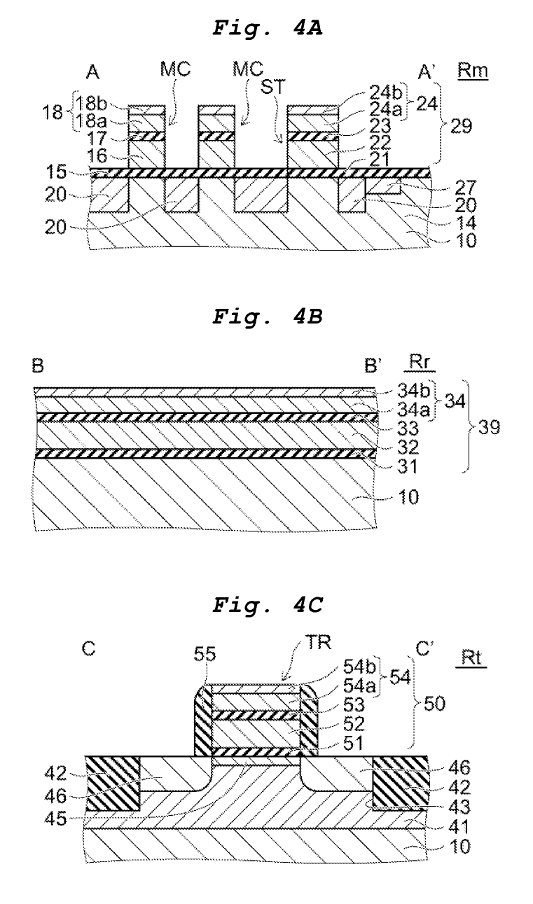

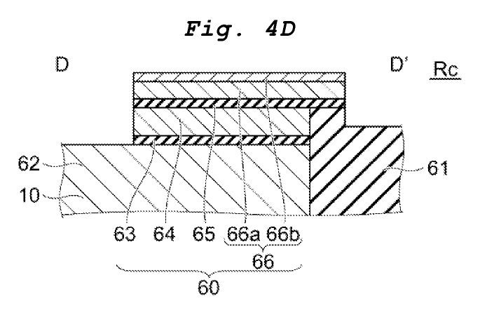

FIG. 4A to FIG. 4D are process cross sections illustrating the method for manufacturing the memory device of an example embodiment.

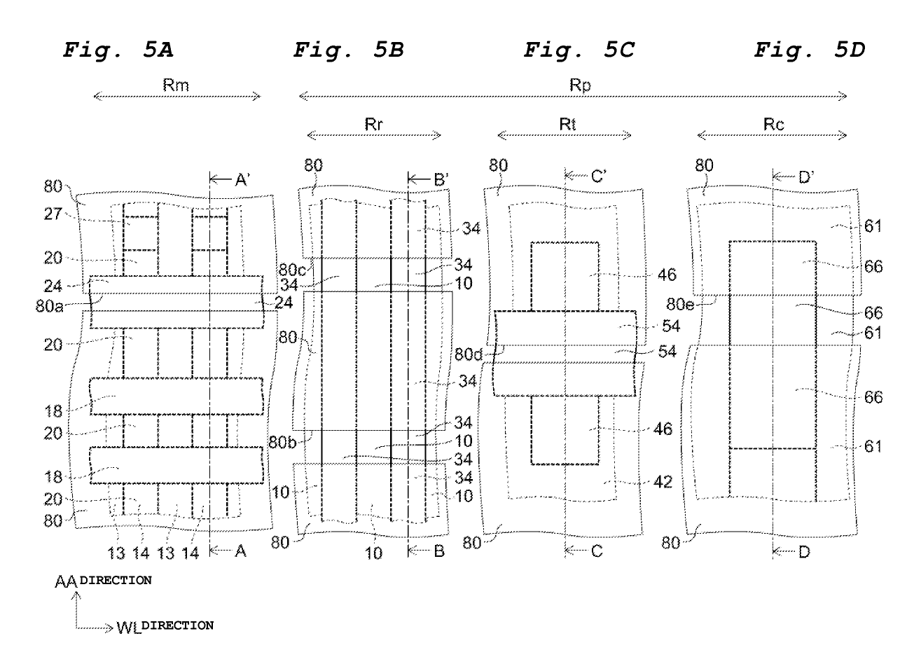

FIG. 5A to FIG. 5D are process plan views illustrating the method for manufacturing the memory device according to this embodiment.

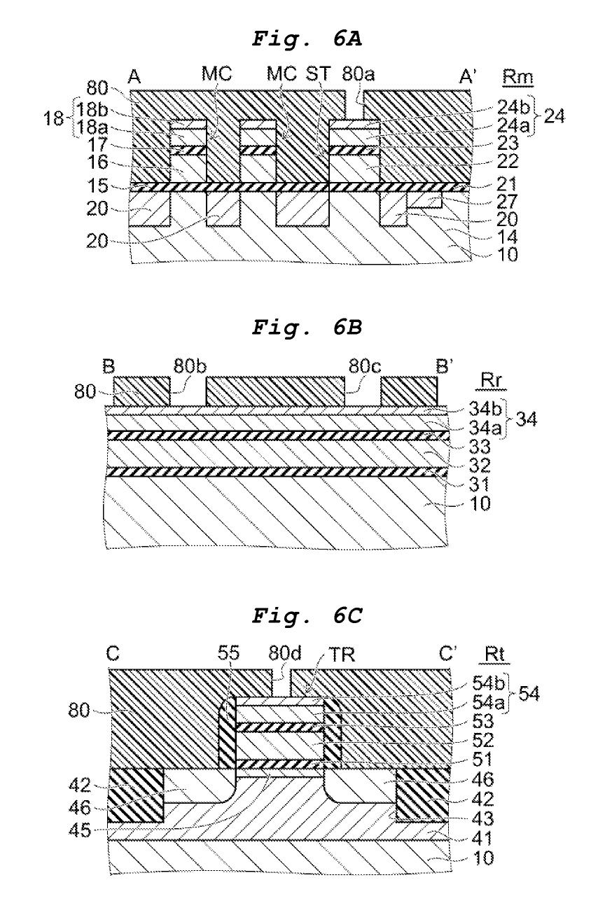

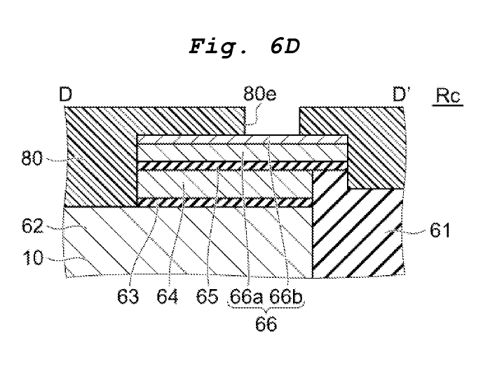

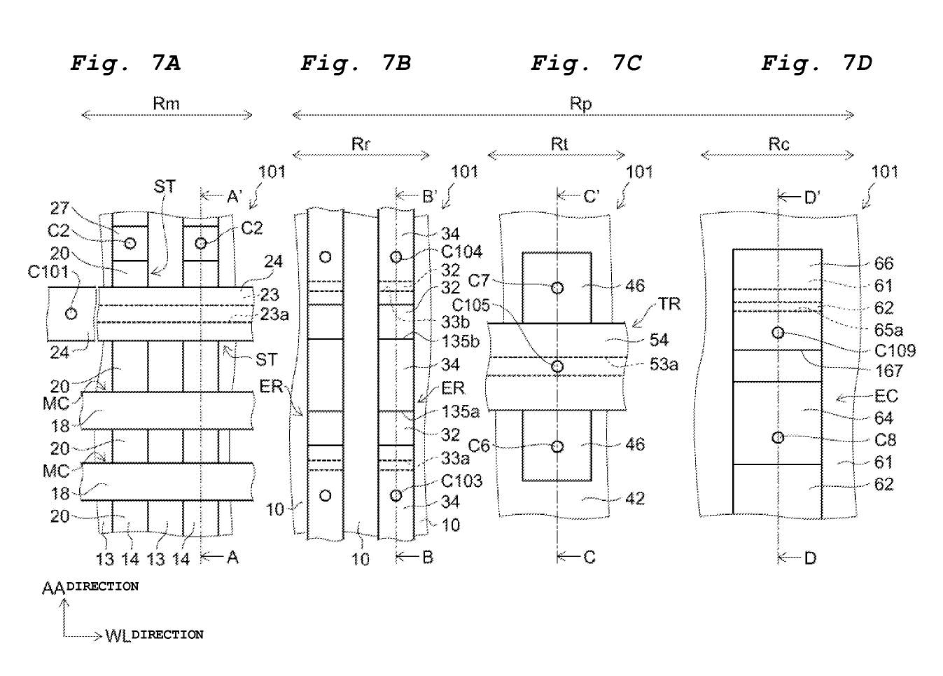

FIG. 6A to FIG. 6D are process cross sections illustrating the method for manufacturing the memory device according to this embodiment.

FIG. 3 and FIG. 4 show the same process, and FIG. 5 and FIG. 6 show the same process. In addition, A-D of each figure show the same positions as those of FIG. 1A to FIG. 1D and FIG. 2A to FIG. 2D.

First, as shown in FIG. 3A to FIG. 3D and FIG. 4A to FIG. 4D, the silicon substrate 10 is prepared. A well including the well 41 is then formed in part of the upper layer portion of the silicon substrate 10. Next, a trench is formed in part of the upper layer portion of the silicon substrate 10, and a silicon oxide is embedded into the trench, forming an element isolation insulator including the STI 13, STI 42, and STI 61. Therefore, in the memory cell region Rm, the upper layer portion of the silicon substrate 10 is divided into several pieces of active areas 14 by the STI 13, and in the transistor region Rt, the upper layer portion of the silicon substrate 10 is divided into the element areas 43 by the STI 42. In the capacitive element region Rc, the upper layer portion of the silicon substrate 10 is divided into the active areas 62 by the STI 61.

Next, a lower layer insulating film including the tunnel insulating film 15, gate insulating film 21, insulating film 31, gate insulating film 51, and insulating film 63 is formed on the upper surface of the silicon substrate 10. At that time, these insulating films are not required to be formed by the same process. For example, after forming a certain insulating film, this insulating film may selectively be removed, and another insulating film may be formed in the removed area. This process may be repeated. Next, with the ion implantation of impurities, the channel region 45 is formed in the upper layer portion of the element area 43 of the transistor region Rt.

Next, for example, polysilicon into which impurities have been introduced is deposited to form a lower conductive film. The lower conductive film is then selectively removed by anisotropic etching such as RIE (reactive ion etching), for instance. Therefore, in the memory cell region Rm, the lower conductive film is processed in a wiring shape extending in the AA direction. In other word, the lower conductive film is divided along the WL direction.

Next, for example, a silicon oxide film and a silicon nitride film are deposited to form an IPD film. A polysilicon layer is then formed, for example, by depositing polysilicon into which impurities have been introduced. Next, a metal layer is formed by depositing a metal such as tungsten or nickel. Here, as the metal layer, a silicide layer may be formed. The silicide layer may be formed by depositing and heating a metal on the polysilicon layer or may also be formed by depositing metal silicide. Therefore, an upper conductive film in which the lower layer is a polysilicon layer and the upper layer is a metal layer is formed.

Next, the upper conductive film, IPD film, lower conductive film, and lower layer insulating film are selectively removed. At that time, the memory cell region Rm is processed by a side wall method. In other words, several pieces of core members (not shown in the drawing) extending in the WL direction are formed and slimmed to make the width of each core member finer. Next, a side wall material is deposited and etched back to form side walls on the side surfaces of the core members. However, at both ends of the core members, the side walls are formed in a loop shape. Next, the core members are removed. Anisotropic etching such as RIE is then applied using the side walls as a mask. Therefore, the upper conductive film remains only beneath the side walls.

As a result, in the memory cell region Rm, the upper conductive film is processed into a wiring shape extending in the WL direction, forming the control gate electrode film 18 and the upper conductive film 24. The IPD film is also processed into a wiring shape extending in the WL direction, forming the IPD film 17 and the IPD film 23. On the other hand, the lower conductive film is divided along the WL direction in the previous process and divided along the AA direction in this process, so that the lower conductive film is divided into both the AA direction and the WL direction. Thereby, the floating gate electrode film 16 and the upper conductive film 22 are formed. The gate insulating film 21, lower conductive film 22, IPD film 23, and upper conductive film 24 form the selective gate insulator 29 extending in the WL direction. However, both ends (not shown in the drawing) in the WL direction of the control gate electrode film 18 and the upper conductive film 24 have a loop shape (the sidewall material covers core member ends as well as sides, thus forming end loops when the core members are removed, these end loops generally must be cut/removed to form final alternating lines/space patterns).

In the resistance element region Rr, the upper conductive film, IPD film, lower conductive film, and lower layer insulating film are processed into a stripe shape, forming the upper conductive film 34, IPD film 33, lower conductive film 32, and insulating film 31, respectively. Therefore, the resistance laminate 39 in which the insulating film 31, lower conductive film 32, IPD film 33, and upper conductive film 34 are sequentially laminated is formed.

In the transistor region Rt, the upper conductive film, IPD film, lower conductive film, and lower layer insulating film are processed into a wiring shape so that these films pass through the area right on the central part in the width direction of the element area 43. These films are respectively turned to the upper conductive film 54, IPD film 53, lower conductive film 52, and gate insulating film 51. Therefore, the gate laminate 50, in which the gate insulating film 51, lower conductive film 52, IPD film 53, and upper conductive film 54 are sequentially laminated, is formed.

In the capacitive element region Rc, the upper conductive film, IPD film, lower conductive film, and lower layer insulating film are processed into a prescribed shape, forming the upper conductive film 66, IPD film 65, lower conductive film 64, and insulating film 63, respectively. Therefore, the capacitive laminate 60 in which the insulating film 63, lower conductive film 64, IPD film 65, and upper conductive film 66 are sequentially laminated from the lower layer side is formed.

Next, using each laminate patterned as mentioned above as a mask, impurities are ion-implanted into the upper layer portion of the silicon substrate 10. Therefore, in the memory cell region Rm, the source-drain region 20 and the contact layer 27 are formed. In addition, the source-drain region 46 is formed in the transistor region Rt. Next, an insulating material is deposited and etched back to form the side wall 55. In this manner, the structures shown in FIG. 3A to FIG. 3D and FIG. 4A to FIG. 4D are prepared.

Next, as shown in FIG. 5A to FIG. 5D and FIG. 6A To FIG. 6D, a mask film 80 is formed on the entire surface. Originally, the mask film 80 is a mask for loop cut for removing the end of a loop shape of the control gate electrode film 18 and the upper conductive film 24. An opening part (not shown in the drawing) for loop cut is added to the mask film 80 to form opening parts 80a-80e, which will be explained below. These opening parts are formed by a lithographic method.

The opening part 80a is formed in a groove shape extending in the WL direction in the area right on the central part in the width direction of the selective gate laminate 29 extending in the WL direction in the memory cell region Rm. The opening parts 80b and 80c are formed in a groove shape extending in the direction orthogonal to the extending direction of the resistance laminate 39 in part of the area right on the resistance laminate 39 in the resistance element region Rr of the peripheral circuit region Rp. In addition, the opening part 80b and the opening part 80c are formed at the positions separated from each other in the extending direction of the resistance laminate 39. The opening part 80d is formed in a groove shape extending in the same direction as that of the gate laminate 50 in the area right on the central part in the width direction of the gate laminate 50 extending in one direction, in the transistor region Rt. The opening part 80e is formed in part of the area right on the capacitive laminate 60 in the capacitive element region Rc.

Next, using the mask film 80 as a mask, for example, etching such as wet-etching is applied. Therefore, the upper conductive film is removed in the area right under the opening parts 80a-80e of the mask film 80. Here, as mentioned above, the control gate electrode film 18, upper conductive film 24, upper conductive film 34, upper conductive film 54, and upper conductive film 66 are included in the upper conductive film.

As a result, in the memory cell region Rm, the loop-shaped part (not shown in the drawing) of the control gate electrode film 18 and the upper conductive film 24 is removed.

In addition, as shown in FIG. 1A to FIG. 1D and FIG. 2A to FIG. 2D, the upper conductive film 24 is selectively removed in the memory cell region Rm, forming the opening part 25. The IPD film 23 is exposed to the bottom face of the opening part 25. In the resistance element region Rr, the upper conductive film 34 is selectively removed, forming the opening parts 35a and 35b. The IPD film 33 is exposed to the bottom faces of the opening part 35a and 35b. In the transistor region Rt, the upper conductive film 54 is selectively removed, forming the opening part 56. The IPD film 53 is exposed to the bottom face of the opening part 56. In the capacitive element region Rc, the upper conductive film 66 is selectively removed, forming the opening part 67. The IPD film 65 is exposed to the bottom face of the opening part 67. The mask film 80 (see FIG. 5 and FIG. 6) is then removed.

Next, as shown in FIG. 1A to FIG. 1D and FIG. 2A to FIG. 2D, an insulating material is deposited and etched back to form the side wall insulating films 68 in the capacitive element region Rc. The liner films 69 are then formed by depositing a silicon nitride, for instance.

Next, for example, a silicon oxide is deposited and flattened to form the interlayer dielectric 30 on the entire surface of the memory device. The interlayer dielectric 30 is formed on the silicon substrate 10 and covers the floating gate electrode film 16, control gate electrode film 18, selective gate laminate 29, resistance laminate 39, gate laminate 50, and capacitive laminate 60.

Next, a mask film (not shown in the drawing) is formed on the interlayer dielectric 30. An opening part is then formed in the area where the contacts C1-C9 in the mask film are formed. Next, using this mask film as a mask, etching such RIE is applied. This etching is carried out under the condition in which the etching rate of the silicon oxide is markedly higher than the etching rate of silicon, that is, the condition in which the etching selection ratio of the silicon oxide to the silicon is increased. Therefore, contact holes H1-H9, which penetrate through the interlayer dielectric 30 and arrive at a conductive part, are formed in portions corresponding to the area right under the opening part of the mask film in the interlayer dielectric 30.

The contact hole H1 passes through the opening part 25 in the memory cell region Rm, penetrates through the IPD film 23, and arrives at the lower conductive film 22. The upper conductive film 24 is not exposed to the inner surface of the contact hole H1. The contact hole H2 arrives at the contact layer 27 in the memory cell region Rm. In the resistance element Rr, the contact holes H3 and H4, respectively, pass through the inside of the opening parts 35a and 35b, penetrate through the IPD film 33, and arrive at the lower conductive film 32 of the resistance laminate 39. The upper conductive film 34 is not exposed to the inner surface of the contact holes H3 and H4.

The contact hole H5 passes through the opening part 56 in the transistor region Rt, penetrates through the IPD film 53, and arrives at the lower conductive film 52 of the gate laminate 50. The upper conductive film 54 is not exposed to the inner surface of the contact hole H5. The contact holes H6 and H7 respectively arrive at the source-drain regions 46 different from each other in the transistor region Rt. The contact hole H8 arrives at the metal layer 66b of the upper conductive film 66 of the capacitive laminate 60 in the resistance element region Rc. The contact hole H9 passes through the opening part 67 in the resistance element region Rc, penetrates through the IPD film 65, and arrives at the lower conductive film 64 of the capacitive laminate 60. The upper conductive film 66 is not exposed to the inner surface of the contact hole H9.

At that time, since the contact holes H1-H9 are formed under the same etching conditions, the amount of overetching of the bottom face of each contact hole depends upon the material of a conductive member of the arrival destination. Since the polysilicon for forming the lower conductive film is softer and more easily etched than the single crystal silicon that forms the silicon substrate 10, the amount of overetching increases. In other words, the amount of overetching is smallest in the contact hole H8 arrived at the metal layer 66b, is small in the contact holes H2, H6, and H7 arrived at the silicon substrate 10, and is the largest in the contact holes H1, H3, H4, H5, and H9 arrived at the lower conductive film.

Next, a conductive material is embedded into the contact holes H1-H9 to form the contacts C1-C9, respectively. An upper layer wiring including a source line and the bit lines is then formed on the interlayer dielectric 30. In this manner, the memory device 1 of this embodiment is manufactured.

Next, the effects of this embodiment will be explained.

In this embodiment, the opening parts 25, 35a, 35b, 56, and 67 are formed in the upper conductive films 24, 34, 54, and 66 and penetrated through the IPD films 23, 33, 53, and 65 when the contact holes H1, H3, H4, H5, and H9 are processed, so that the contacts C1, C3, C4, C5, and C9 are made to directly arrive at the lower conductive films 22, 32, 52, and 64, thereby being able to connect these films. For this reason, in the IPD films 23, 33, 53, and 65, it is unnecessary to form opening parts for connecting the upper conductive films to the lower conductive films. Therefore, the manufacturing processes of the memory device 1 can be simplified, thus being able to reduce the manufacture cost of the memory device 1.

In addition, according to this embodiment, in the processes shown in FIG. 5 and FIG. 6, etching is carried out using one sheet of mask film 80, thus being able to simultaneously form the opening parts 25, 35a, 35b, 56, and 67. As a result, the manufacturing processes of the memory device 1 can be further simplified, thus being able to further reduce the manufacture cost of the memory device 1.

Moreover, in this embodiment, in the etching process for loop-cutting the control gate electrode film 18 as a word line of the memory cell region Rm, the opening part 25, 35a, 35b, 56, and 67 are formed. Therefore, loop-cutting and forming of the opening parts can be carried out by one sheet of mask film 80, so that it is unnecessary to add a lithographic process and an etching process to form the opening parts. Since the lithographic process is a process with especially high process unit price, the reduction effect of the manufacture cost of the memory device through the elimination of the lithographic process is especially significant.

Furthermore, in this embodiment, the floating gate electrode film 16 and the lower conductive films 22, 32, 52, and 64 are formed by patterning one sheet of conductive film, the IPD films 17, 23, 33, 53, and 65 are formed by patterning one sheet of conductive film, and the control gate electrode film 18 and the upper conductive films 24, 34, 54, and 66 are formed by pattering one sheet of conductive film. For these reasons, the manufacturing processes of the memory device 1 of this embodiment are simple.

In addition, in this embodiment, the upper conductive film is a double layer film in which a polysilicon layer and a metal layer are laminated. Therefore, with the installation of the metal layer in the upper conductive film, the wiring resistance of the control gate electrode film 18 as a word line in the memory cell region Rm can be lowered.

Next, a comparative example will be explained.

FIG. 7A to FIG. 7D shows plan views illustrating a memory device of this comparative example. FIG. 7A shows memory cells and a selective gate transistor, FIG. 7B shows a resistance element, FIG. 7C shows a transistor, and FIG. 7D shows a capacitive element.

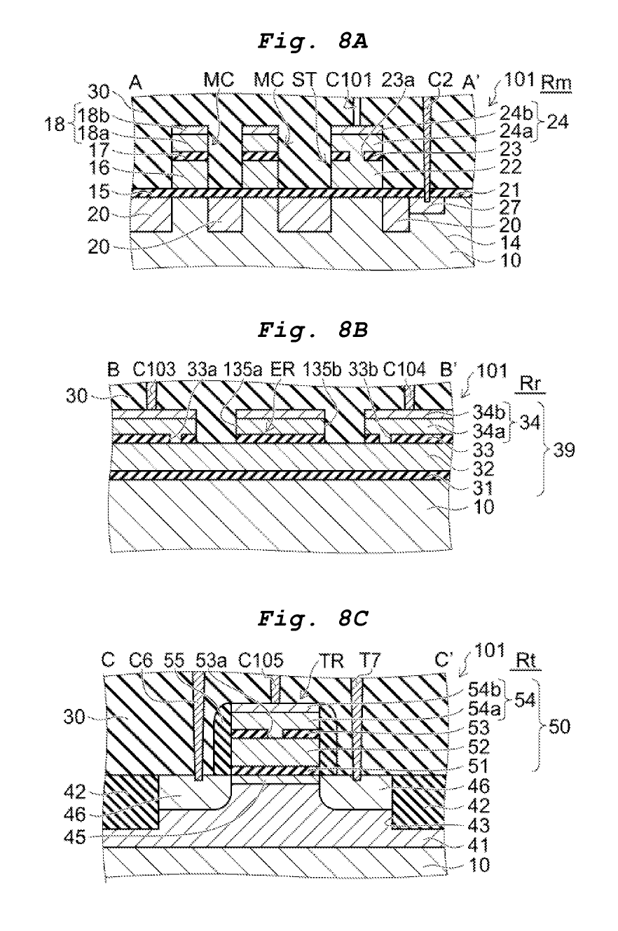

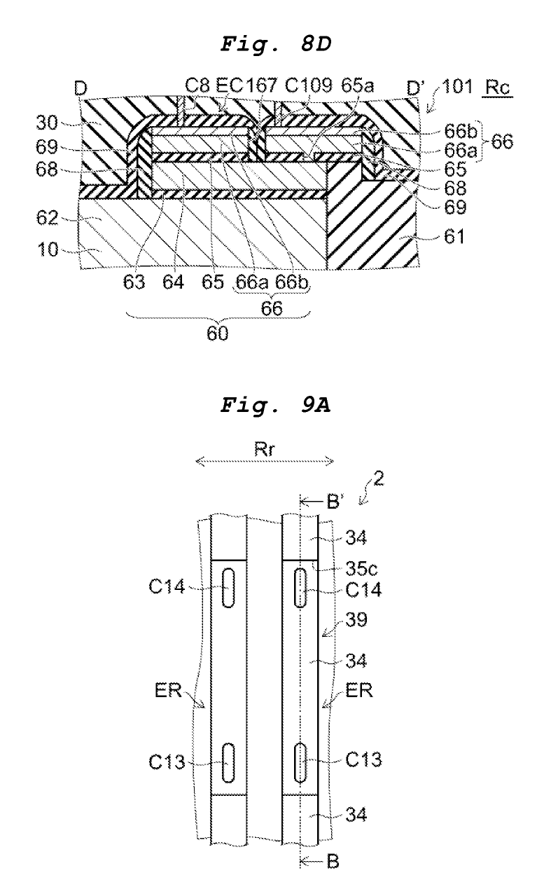

FIG. 8A to FIG. 8D show cross sections illustrating the memory device of this comparative example. FIG. 8A is a cross section along A-A′ line of FIG. 7A, FIG. 8B is a cross section along B-B′ line of FIG. 7B, FIG. 8C is a cross section along C-C′ line of FIG. 7C, and FIG. 8D is a cross section along D-D′ line of FIG. 7D.

As shown in FIG. 7A to FIG. 7D and FIG. 8A to FIG. 8D, in a memory device 101 of this comparative example, a contact is connected to an upper conductive film, and part of a portion connected to the contact in the upper conductive film is connected to a lower conductive film via an opening part formed in an IPD film. Therefore, a partial contact is connected to the lower conductive film via the upper conductive film.

Next, the memory device of this comparative example will be explained in detail.

As shown in FIG. 7A and FIG. 8A, in a memory cell region Rm, a contact C101 is formed instead of the contact C1 (see FIG. 1A) and connected to a metal layer 24b of the upper conductive film 24. In addition, an opening part 23a is formed in the IPD film 23, and a polysilicon layer 24a of the upper conductive film 24 advances into the opening part 23a, contacting with the lower conductive film 22. Therefore, the contact C101 is connected to the lower conductive film 22 via the upper conductive film 24. Here, the contact C101 is formed in an area separated from the area above active areas 14.

As shown in FIG. 7B and FIG. 8B, in the resistance element region Rr, contacts C103 and C104 are formed instead of the contacts C3 and C4 (see FIG. 1B) and connected to a metal layer 34b of the upper conductive film 34. In addition, opening parts 33a and 33b are formed in the IPD film 33, and a polysilicon layer 34a of the upper conductive film 34 advances into the opening parts 33a and 33b, contacting with the lower conductive film 32. Therefore, the contacts C103 and C104 are respectively connected to the lower conductive film 32 via the upper conductive film 34. Moreover, opening parts 135a and 135b are formed in the upper conductive film 34. Therefore, the contact C103 in the upper conductive film 34 is connected, and the contact 104 in the upper conductive film 34 is connected to the portion advanced into the opening part 33a and electrically separated from the portion advanced into the opening part 33b by the opening parts 135a and 135b. As a result, the contacts C103 and C104 are prevented from being short-circuited via the upper conductive film 34.

As shown in FIG. 7C and FIG. 8C, in the transistor region Rt, a contact C105 is formed instead of the contact C5 (see FIG. 1C) and connected to a metal layer 54b of the upper conductive film 54. In addition, an opening part 53a is formed in the IPD film 53, and a polysilicon layer 54a of the upper conductive film 54 advances into the opening part 53a, contacting with the lower conductive film 52. Therefore, the contact C105 is connected to the lower conductive film 52 via the upper conductive film 54.

As shown in FIG. 7D and FIG. 8D, in a capacitive element region Rc, a contact C109 is formed instead of the contact C9 (see FIG. 1D) and connected to a metal layer 66b of the upper conductive film 66. In addition, an opening parts 65a is formed in the IPD film 65, and a polysilicon layer 66a of the upper conductive film 66 advances into the opening part 65a, contacting with the lower conductive film 64. Therefore, the contact C109 is connected to the lower conductive film 64 via the upper conductive film 66. Moreover, an opening part 167 is formed in the upper conductive film 66. Therefore, the contact C109 in the upper conductive film 66 is connected, and the portion advanced into the opening part 65a is electrically separated from the portion connected with the contact 8 in the upper conductive film 66 by the opening part 167. As a result, the contacts C109 and C8 are prevented from being short-circuited via the upper conductive film 66.

In this comparative example, to connect the upper conductive film to the lower conductive film, it is necessary to form an opening part in the IPD film. For this reason, compared with the first embodiment, one more lithographic process is required, raising the manufacture cost of the memory device.

Next, a second embodiment will be explained.

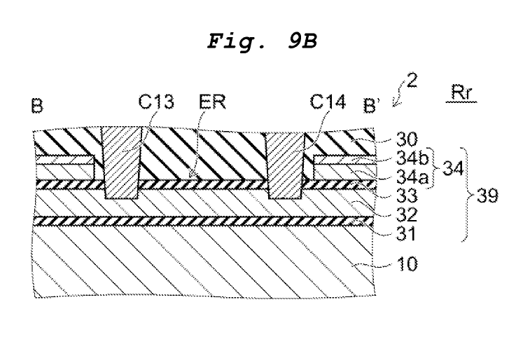

FIG. 9A is a plan view illustrating a resistance element of the memory device according to this embodiment, and FIG. 9B is a cross section along B-B′ line of FIG. 9A.

The areas shown in FIG. 9A and FIG. 9B, respectively, correspond to the areas shown in FIG. 1B and FIG. 2B.

As shown in FIG. 9A and FIG. 9B, a memory device 2 of this embodiment is different from the memory device 1 (see FIG. 1 and FIG. 2) of the first embodiment in that contacts C13 and C14 with a long circular (oval or rectangular with rounded corners) shape viewed from above are formed instead of the contacts C3 and C4 (see FIG. 1B) with a circular shape viewed from above. From the top view, the longitudinal direction of the contacts C13 and C14 are matched with the extending direction of the resistance laminate 39.

In addition, compared with the memory device 1, in the memory device 2, one large opening part 35c is formed in the upper conductive film 34 in the resistance element region Rr, and the contacts C13 and C14 pass through the opening part 35C and arrive at the lower conductive film 32. In other words, in the memory device 2, the upper conductive film 34 is not formed in the entire area between the contacts C13 and C14 in the resistance element ER. This memory device 2 can be manufactured by forming one large opening part in an area including the area where the opening parts 80b and 80c are formed, instead of forming two opening parts 80b and 80c in the mask film 80 in the processes shown in FIG. 5 and FIG. 6.

According to this embodiment, since the contacts C13 and C14 with a long circular shape observed from the top, the resistance of the contacts themselves and the contact resistance between the contacts and the lower conductive film can be lowered, compared with the first embodiment. In addition, since one large opening part may be formed in the mask film 80 in the resistance element region Rr, the lithography is made easy. The other constitutions, manufacturing method, and operation effect in this embodiment are similar to those of the first embodiment.

According to the embodiments explained above, the memory device and its manufacturing method can be realized at low cost.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device, comprising:
a semiconductor substrate with a memory cell region and a peripheral circuit region thereon;
a lower layer insulating film formed on the semiconductor substrate;
a floating gate electrode film formed on the lower layer insulating film in the memory cell region;
a first inter-electrode insulating film formed on the floating gate electrode film;
a control gate electrode film formed on the first inter-electrode insulating film;
a lower conductive film formed on the lower layer insulating film in the peripheral circuit region;
a second inter-electrode insulating film formed on the lower conductive film;
an upper conductive film formed on the second inter-electrode insulating film; and
a pair of contacts separated from each other, connected to the lower conductive film from above, and not connected to the upper conductive film, wherein
the lower conductive film comprises the same material as the floating gate electrode film;
the second inter-electrode insulating film comprises the same as material as the first inter-electrode insulating film; and
the upper conductive film comprises the same material as the control gate electrode film.

2. The memory device according to claim 1, wherein a first opening and a second opening are formed in the upper conductive film, and a first contact of the pair of contacts passes through the first opening and a second contact of the pair of contacts passes through the second opening.

4. The memory device according to claim 1, wherein a first opening is formed in the upper conductive film and the pair of contacts passes through first opening.

5. The memory device according to claim 1, wherein,
the control gate electrode film has a first polysilicon layer and a first metal layer installed on the first polysilicon layer; and
the upper conductive film has a second polysilicon film and a second metal layer installed on the second polysilicon layer.

6. The memory device of claim 1, further comprising a third contact connected to an upper surface of the semiconductor substrate, but not connected to the second conductive film.

7. The memory device according to claim 1, further comprising a third insulating layer formed on the semiconductor substrate, wherein the pair of contacts extends through the third insulating layer.

8. The memory device according to claim 7, further comprising, one or more layers of memory cells stacked above the third insulating layer.

9. A method for manufacturing a memory device including a memory cell region and a peripheral circuit region, the method comprising:
forming a first insulating film on a semiconductor substrate;
forming a first conductive film on the first insulating film;
forming a second insulating film on the first conductive film;
forming a second conductive film on the second insulating film;
removing portions of the first conductive film in a memory cell region;
removing portions of the first conductive film, the second insulating film, and the second conductive film;
forming an opening in the second conductive film and the second insulating film to expose an upper surface of the first conductive film;
forming a third insulating film over the first insulating film, the first conductive film, the second insulating film, and the third conductive film, the third insulating film filling the opening in the second conductive film and the second insulating film; and
forming a plurality of contacts through the third insulating film in a single etching process, the contacts connecting to an upper surface of the silicon substrate or the upper surface of the first conductive film, wherein at least one contact passes through the opening in the second conductive film and the second insulating film.

10. The method of claim 9, wherein more than one contact passes through the opening in the second conductive film and the second insulating film.

11. The method of claim 10, wherein the single etching process for forming the plurality of contacts is a reactive ion etch.

12. The method of claim 9, wherein removing portions of the first conductive film in the memory cell region includes a trim etch to decrease the width of a feature formed in the first conductive film.

13. The method of claim 9, wherein removing portions of the first conductive film, the second insulating film, and the second conductive film includes a step of depositing a sidewall material and generates a pattern having a loop end.

14. The method of claim 13, wherein the loop end of the generated pattern is removed when the opening in the second insulating film and the second conductive film is formed.

15. The method of claim 9, further comprising implanting dopants into regions of the silicon substrate after the step of removing portions of the first conductive film, the second insulating film, and the second conductive film.

16. The method of claim 9, wherein the first insulating film comprises layers of different thicknesses or material depending on location within the memory device.

17. The method of claim 9, wherein the second conductive layer comprises a polysilicon layer and a metal layer on the polysilicon layer.

18. A method for manufacturing a memory device that includes a memory cell region and a peripheral circuit region, the method comprising:
forming a lower layer insulating film on a semiconductor substrate;
forming a lower conductive film on the lower layer insulating film;
selectively removing the lower conductive film in the memory cell region as a result of which the lower conductive film has a wiring shape extending in a first direction;
forming an inter-electrode insulating film on the lower conductive film;
forming an upper conductive film on the inter-electrode insulating film;
forming a control gate electrode extending in a second direction, the second direction intersecting with the first direction, the control gate electrode formed by selectively removing the upper conductive film, the inter-electrode insulating film, and the lower conductive film;
forming a floating gate electrode film by selectively removing the lower conductive film to divide the lower conductive along both the first direction and the second direction;
forming a resistance laminate in which the lower layer insulating film, the lower conductive film, the inter-electrode insulating film, and the upper conductive film are sequentially laminated;
forming a mask film that covers the floating gate electrode film, the control gate electrode film, and the resistance laminate, the mask film with a mask opening above at least a portion the resistance laminate;
forming an opening in the upper conductive film of the resistance laminate by etch processing using the mask film;
forming an interlayer dielectric that covers the floating gate electrode film, the control gate electrode film, and the resistance laminate; and
forming a pair of contacts that penetrates through the interlayer dielectric film, passes through the opening in the upper conductive film, and contacts the lower conductive film of the resistance laminate, the pair of contacts not electrically connected to the upper conductive film.

19. The method for manufacturing the memory device according to claim 18, wherein
during said forming of a control gate electrode film, the control gate electrode film is formed the patterning process includes a sidewall method in which lines of a first patterned material are narrowed by an isotropic etch process, an insulating material is deposited on the sidewalls of the narrowed first patterned material, the first patterned material is removed leaving the insulating material as a pattern, the pattern in the insulating material is then transferred to the upper conductive film by etch processing and
the control gate electrode film is subjected to a loop cut process whereby the pattern formed in the insulation material is modified by removing loops formed at line ends by the sidewall method.

20. The method for manufacturing the memory device according to claim 18, wherein forming the upper conductive film includes:
forming a polysilicon layer and a metal layer on the polysilicon layer.
